(19) United States
(12) Patent Application Publication
(10) Pub. No.: US 2002/0048897 A1
(43) Pub. Date: Apr. 25, 2002

(54) Method of forming a self-aligned shallow trench isolation

(75) Inventor: Uk-Sun Hong, Seoul (KR)

Correspondence Address: MILLS & ONELLO LLP, Eleven Beacon Street, Suite 605, Boston, MA, 02108, US

(73) Assignee: Samsung Electronics Co., Ltd.

(21) Appl. No.: 09/864,627

(22) Filed: May 24, 2001

(30) Foreign Application Priority Data
May 26, 2000 (KR) 28595/2000

(51) Int. Cl. H01L 21/76

(52) U.S. Cl. 438/424

(57) ABSTRACT

A method for fabricating a semiconductor device, for example a non-volatile memory device having a stacked gate (memory cell) consisting of a floating gate, a control gate deposited over the floating gate, and a dielectric interlayer interposed between them, comprises the steps of sequentially depositing: a tunnel oxide layer, a first polysilicon layer for the floating gate, and a nitride layer over a semiconductor substrate, sequentially etching the nitride layer, first polysilicon layer, and semiconductor substrate to form a trench, depositing an oxide layer over the substrate to fill the trench, removing the oxide layer to the level of the nitride layer to attain a field region of the trench isolation, removing the nitride layer, subjecting the field region to a wet-chemical treatment, and depositing a second polysilicon layer for the floating gate over the substrate.

### BACKGROUND OF THE INVENTION

1. Field of the Invention

The present invention relates to a method for forming a semiconductor device, and more particularly to a method of forming a semiconductor device using shallow trench isolation (STI), thereby reducing the negative slope of the field region.

2. Description of the Related Art

Electrical isolation of circuit elements such as transistors, diodes, resistors, etc. is generally required during the initial steps of semiconductor device production, thus critically affecting the size of the active region as well as the procedural margin of subsequent processes. The customary method for providing such isolation is the LOCOS (LOCal Oxidation of Silicon) technique.

The LOCOS method of element isolation generally consists of sequentially depositing an oxide and nitride layer over a silicon substrate, patterning the nitride layer, and selectively subjecting the silicon substrate to oxidation to form the field oxide layer. According to this method, oxygen penetrates from beneath the nitride layer serving as the selective oxidation mask into the side of the pad oxide layer, generating a so-called “bird's beak” formation at the edges of the field oxide layer. Since such bird's beak extends the field oxide layer into the active region to its length, the channel length is shortened to bring about the so-called “narrow channel effect”, thereby increasing the threshold voltage. This, in turn, degrades the electrical characteristics of the transistor. Particularly, since LOCOS isolation results in a channel length below 0.3 μm, a phenomenon called “punch-through” occurs, connecting the field oxide layers at both sides of the active region, so that the active region is not correctly secured.

In view of this, the STI method is used for a semiconductor device fabrication according to the design rule of less than 0.25 μm. The STI process generally comprises the steps of etching a silicon substrate to form a trench with a given depth, depositing an oxide layer over the substrate including the trench, and etching the oxide layer by etch back or chemical mechanical polishing (CMP) process to form the active region with the trench filled flat with the oxide layer. The undoped silicate glass (USG) or ozone-tetraethylorthosilicate (O₃-TEOS USG) has been primarily used as the oxide layer for filling the trench. However, as the aspect ratio of the trench increases so that the trench is not completely filled with the USG layer, voids occur within the trench. Hence, high-density plasma oxide tends to be used, having greater stability and more suitable properties for filling the gap, rather than the USG layer.

FIGS. 1 to 4 are cross sectional views of a conventional non-volatile memory device for illustrating the conventional method of forming a device using self-aligned shallow trench isolation (SA-STI), which may reduce the size of the memory cell by making the active pattern identical with the floating gate pattern.

Referring to FIG. 1, sequentially deposited over a silicon substrate 10 are a tunnel oxide layer 12, first polysilicon layer 14, nitride layer 16, and high-temperature oxide layer (not shown). The first polysilicon layer 14 is used for the floating gate.

Photolithography is performed on the high-temperature oxide layer of the active region to produce a patterned mask, according to which the nitride layer 16 and first polysilicon layer 14 are sequentially etched to produce the active pattern defining the active region. Then, the substrate 10 is etched to a predetermined depth to form a trench using the patterned mask of the high temperature oxide layer. Subsequently, although not shown, in order to treat the silicon damage caused by the impact of high-energy ions during etching the trench 18, the side walls of the trench are covered with a thermal oxidation layer, over which is deposited a nitride liner both to prevent leakage current and to improve the characteristics of the gate oxide layer.

Subsequently, deposited over the substrate is an oxide layer 20 of high-density plasma with enough thickness to completely fill the trench 18 by chemical vapor deposition (CVD). The oxide layer 20 of high density plasma may be deposited by generating a high density plasma based on a gas of SiH₄, O₂ and Ar. Namely, SiH₄ and O₂ are combined to form SiO₂ deposited over the wafer, the back-side of which is applied with an RF bias voltage to attract the particles of Ar and O₂ to the surface of the wafer, so as to generate the Ar sputter etch to fill the trench 18. However, during this process, the Ar sputter etch clips both the nitride layer 16 and the first polysilicon layer 14 so that the upper side-walls of the trench 18 form negative slopes at about 60°. Then, the oxide layer 20 of high density plasma is removed by CVD until the surface of the nitride layer 16 is exposed, so as to attain the field region of the STI structure filled flat with the oxide layer 20 of high density plasma.

Referring to FIG. 2, the nitride layer 16 is stripped off by phosphoric acid. This produces empty spaces at the lower edges of the field regions due to the negative slopes of the STI structure. Then, as shown in FIG. 3, a second polysilicon layer 22 is deposited over the substrate, which fills the empty spaces under region “A” with the second polysilicon layer 22, thus increasing the amount of polysilicon under the negative slopes of the field region. The second polysilicon layer 22 is provided to increase the area of the dielectric interlayer subsequently formed, serving as the floating gate together with the first polysilicon layer 14.

Referring to FIG. 4, photolithography is performed to remove the second polysilicon layer 22. Then, deposited over the substrate is a dielectric interlayer of ONO (not shown) both to isolate the control gate from the floating gate and to increase the static electric capacitance. Photolithography is performed to remove the dielectric interlayer, second polysilicon layer 22, and first polysilicon layer 14 in the peripheral circuit region. Then, sequentially deposited over the resulting formation are a third polysilicon layer and tungsten silicide layer (not shown), which in turn is subjected to photolithography to sequentially etch the tungsten silicide layer, third polysilicon layer, dielectric interlayer, second polysilicon layer 22, and first polysilicon layer 14 in the memory cell region and peripheral circuit region, thus forming the stacked gate of the memory transistor. Additional photolithography is performed to etch the tungsten silicide layer and third polysilicon layer in the peripheral circuit region to form the gate of the transistor.

However, the conventional method usually causes the oxide layer to block the polysilicon layer existing below the field region due to the anisotropic property of the dry etching and the selectivity between the polysilicon and the oxide layer. This results in the conductive stringer 24 of the polysilicon part not being etched in the form of a line as shown in FIG. 4. Such a stringer generates a bridge between the adjacent gate patterns, degrading the properties of the semiconductor elements and yield rate.

### SUMMARY OF THE INVENTION

It is an object of the present invention to eliminate the effect of the negative slopes in the field region in formation of a semiconductor device using STI.

According to an aspect of the present invention, provided is a method for fabricating a semiconductor device, for example a non-volatile memory device having a stacked gate (memory cell) consisting of a floating gate, a control gate deposited over the floating gate, and a dielectric interlayer interposed between them. The method comprises the steps of sequentially depositing a tunnel oxide layer, a first polysilicon layer for the floating gate, and a nitride layer over a semiconductor substrate; sequentially etching the nitride layer, first polysilicon layer, and semiconductor substrate to form a trench, depositing an oxide layer over the substrate to fill the trench, removing the oxide layer to the level of the nitride layer to attain a field region of the trench isolation, removing the nitride layer, subjecting the field region to a wet-chemical treatment, and depositing a second polysilicon layer for the floating gate over the substrate.

Preferably, the wet chemical treatment is performed so as to etch the oxide layer by an amount in the range of 100 to 200 Å. It is also preferred to subject the field region to a wet chemical treatment before the step of removing the nitride layer.

The present invention provides a method of changing the negative slopes of the field region into approximately positive slopes by employing the isotropic etching effect of the wet chemical process after removing the nitride layer from the field region of the STI structure.

### BRIEF DESCRIPTION OF THE DRAWINGS

The foregoing and other objects, features and advantages of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIGS. 1 to 4 are cross sectional views of a semiconductor device for illustrating the conventional method of forming the SA-STI;

FIGS. 5 to 10 are cross sectional views of a semiconductor device for illustrating the inventive method of forming the SA-STI; and

FIGS. 11 and 12 are SEM photos of the field structure after forming the gates according to the conventional and inventive methods respectively.

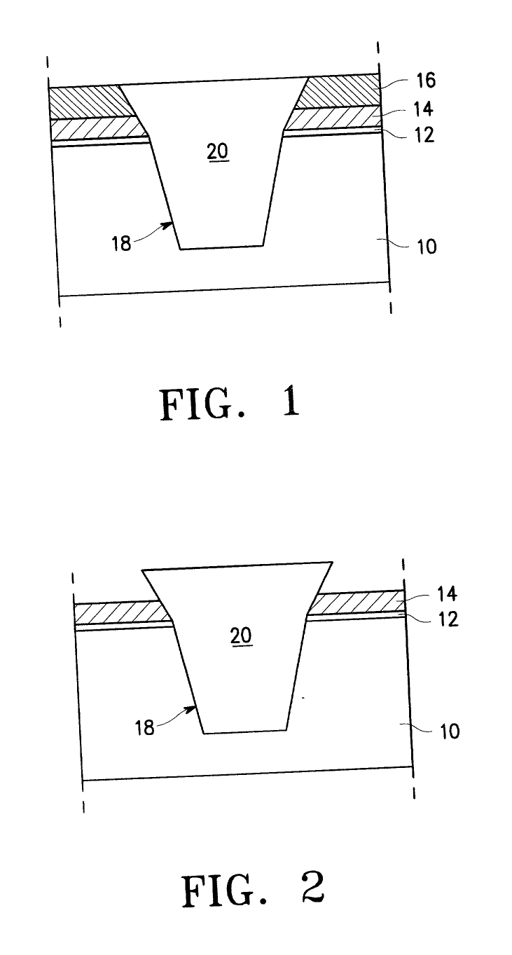

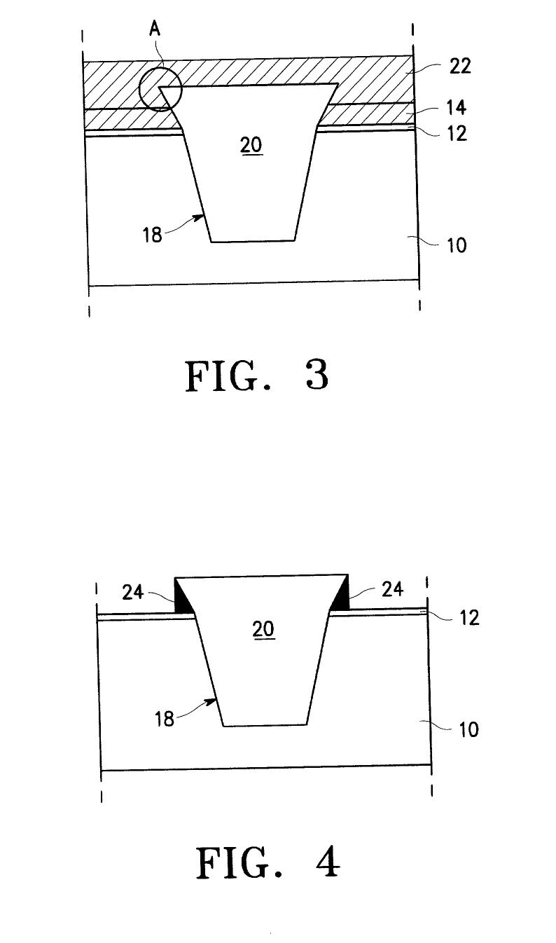

### DETAILED DESCRIPTION OF PREFERRED EMBODIMENTS

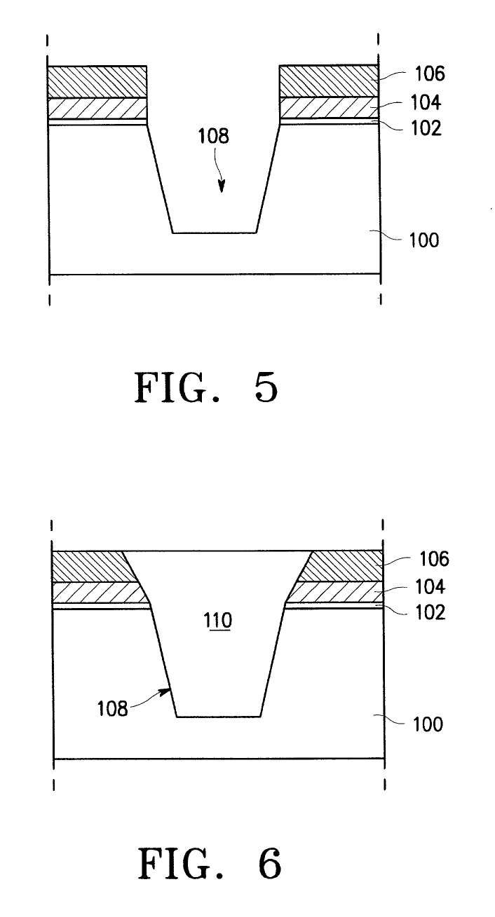

With reference to FIG. 5, the steps of forming the trench in accordance with the present invention will be described. Sequentially deposited over a silicon substrate 100 are a tunnel oxide layer at a thickness of 70 to 100 Å, and a first polysilicon layer 104 by LPCVD (Low Pressure CVD) at a thickness of 300 to 1000 Å. The first polysilicon layer is then doped with highly concentrated N-type impurities.

A nitride layer 106 is deposited on the first polysilicon layer 104 with a thickness of 1500 to 2000 Å by LPCVD, serving as the polishing limit in the subsequent CMP. Deposited over the nitride layer 106 is a high temperature oxide layer (not shown) with a thickness of 1000 to 2000 Å by means of CVD. In addition, an anti-reflective layer (not shown) of SiON is deposited thereon with a thickness of about 800 Å. The anti-reflective layer serves to prevent irregular reflections from occurring in the subsequent photolithography process, and it is removed during the subsequent process of etching the trench. Photolithography is then performed to etch the anti-reflective layer and high temperature oxide layer to form the active pattern defining the active region. The trench 108 is formed by sequentially etching the nitride layer 106, first polysilicon layer 104, and substrate 100 according to the active pattern.

With reference to FIG. 6, formation of the field region will now be described. An oxidation process is performed to deposit a thermal oxidation layer (not shown) on the side-walls of the trench in order to eliminate the damage to the silicon caused by the impact of the high energy ions during the process of etching the trench 108. A nitride liner (not shown) is deposited over the substrate to prevent leakage current and improve the characteristics of the gate oxide layer. CVD is performed to form a high-density plasma oxide layer 110 with a thickness of about 5000 Å. Ar sputter etching is performed on the high-density plasma oxide layer 110 to improve the gap-filling characteristics. In this case, the nitride layer 106 and first polysilicon layer 104 are clipped to negatively slope the upper sidewalls of the trench 108 by about 60° as shown. Subsequently, the high-density oxide layer 110 is subjected to CMP to expose the nitride layer 106, thus obtaining the field region of the STI structure filled flat with the oxide layer.

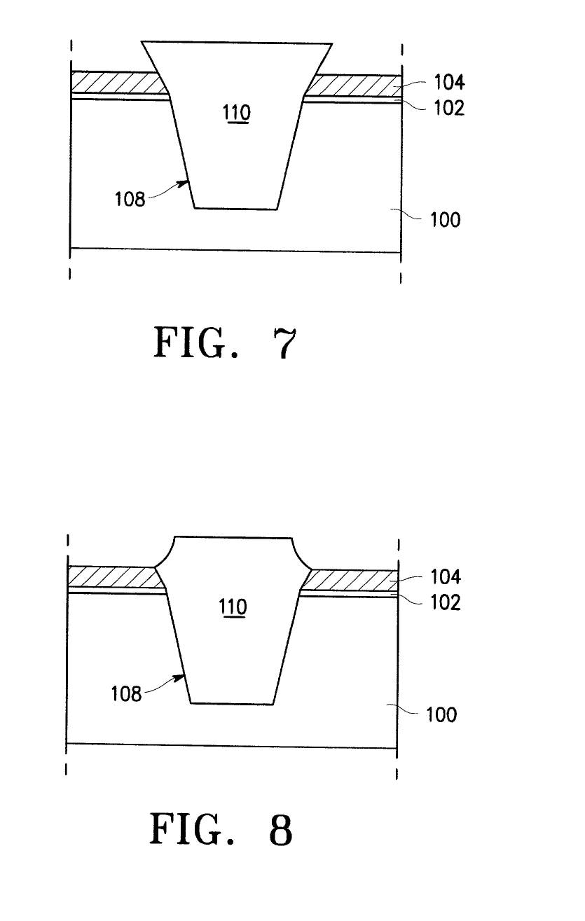

Referring to FIG. 7, the empty spaces are shown beneath the negative slopes in the field region of the STI structure after removing the nitride layer 106. Then, the oxide layer 110 of the field region is subjected to a wet etching by using an etchant such as HF of 100:1, so that the isotropic etching property of the etchant causes the oxide layer 110 to be etched similarly in both vertical and horizontal directions. This rounds off the field region projecting over the first polysilicon layer 104, causing it to have a positive slope as shown. Although an increase of the time taken for the wet chemical treatment makes the field region more rounded, it also decreases the step difference between the field region and active region both in the memory cell region and the peripheral circuit region, so that the subsequent photolithography of the second polysilicon should undergo reduction of the processing margin. Therefore, it is preferable to perform the wet chemical treatment with the etched amount of the oxide layer being in the range of 100 to 200 Å.

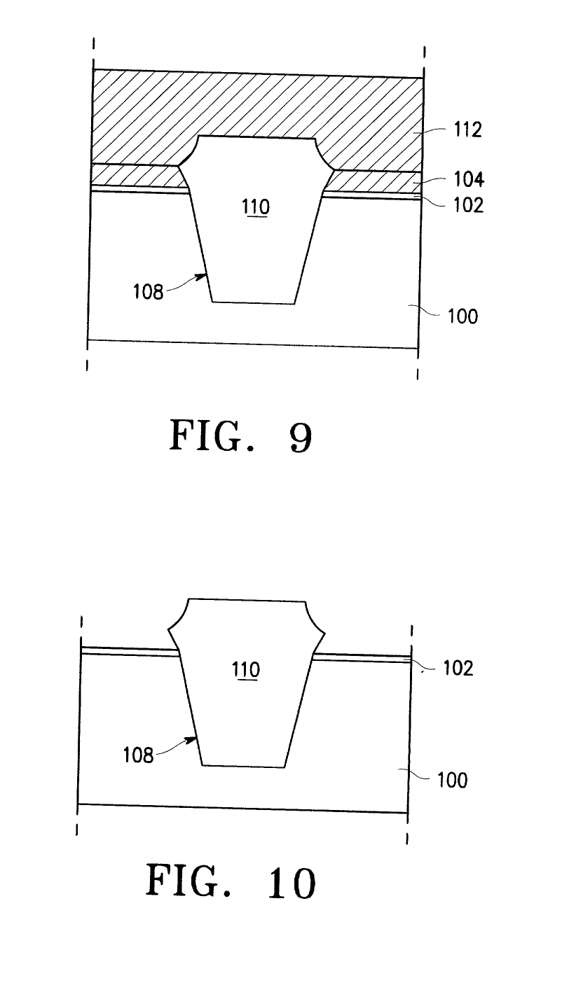

FIG. 9 shows a second polysilicon layer 112 deposited by LPCVD over the substrate with a thickness of more than about 3000 Å for the floating gate. Since there no negative slope is formed during deposition of the second polysilicon layer 112, the polysilicon is not excessively laid in the lower edges of the field region. The second polysilicon layer 112 increases the area of the dielectric interlayer of ONO subsequently formed, serving as the floating gate together with the first polysilicon layer 104. In addition, the second polysilicon layer 112 is doped with highly concentrated N-type impurities, and is then subjected to photolithography to isolate the floating gates of the adjacent cell transistors along the bit line.

Referring to FIG. 10, a dielectric interlayer (not shown) of ONO is deposited over the substrate for the joint purpose of both isolating the control gate from the floating gate of the memory cell transistor and enhancing the static electrical capacitance. Photolithography is performed to remove the dielectric interlayer, the second polysilicon layer 112, and the first polysilicon layer 104 of the peripheral circuit region. Sequentially deposited over the substrate are a third polysilicon layer and tungsten silicide layer (not shown). Additional photolithography is performed to form the stacked gate of the memory cell transistor by etching the tungsten silicide layer, third polysilicon layer, dielectric interlayer, second polysilicon layer 112, and first polysilicon layer 104 in the memory cell and peripheral circuit regions. Again, photolithography is performed to form the gates of the peripheral circuit transistors by etching the tungsten silicide and third polysilicon layer of the peripheral circuit region.

As described above, since the polysilicon is not excessively deposited in the lower edges of the field region due to the round profile, unnecessary polysilicon is completely removed, so as not to generate the conductive residual stringers, in contrast with the conventional process. According to an aspect of the present invention, if the step difference is great, the oxide layer is subjected to a wet chemical treatment to remove about 40 percent of the required etching amount of the oxide layer before removing the nitride layer, thus firstly reducing the negative slopes before generating the round profile in the field region. Then, removing the nitride layer, an additional wet chemical treatment is performed to completely remove the residual 60 percent of the oxide layer, generating the desired rounded profile in the field region.

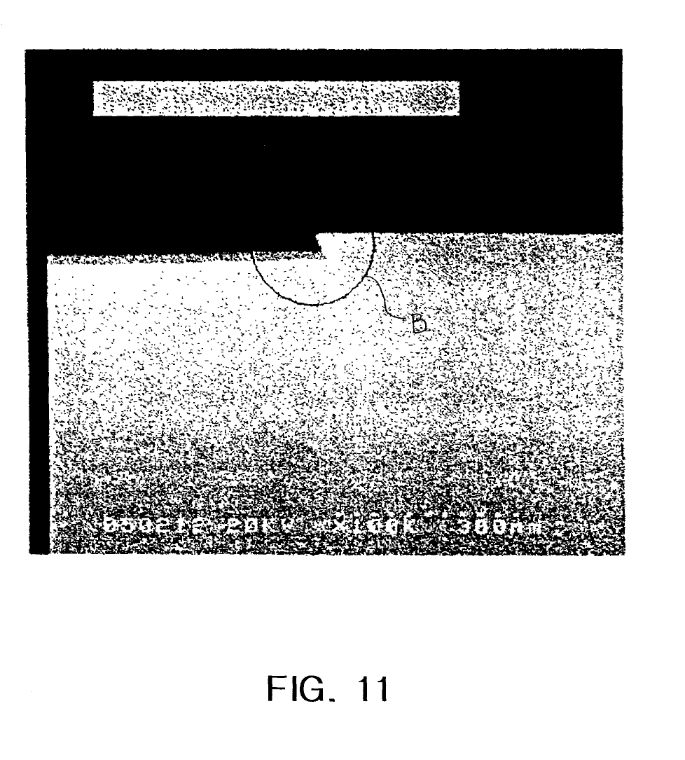

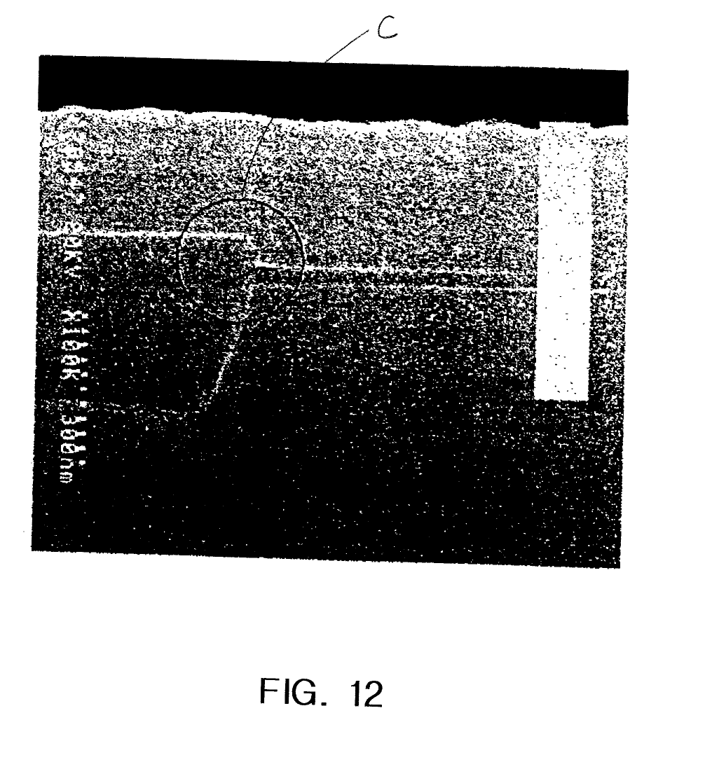

Comparing the SEM photos shown in FIGS. 11 and 12, the conventional method etches the gates with the negative slopes remaining in the field region, so that the polysilicon is not removed from the lower edges of the field region, generating the residual conductive stringers as indicated by “B” in FIG. 11. Such conductive stringers form bridges between the adjacent gate patterns, degrading the properties of the elements and yield rate.

However, the inventive method subjects the oxide layer of the field region to a wet chemical treatment after removing the nitride layer used for the active pattern, so that the negative slopes of the field are changed into the positive slopes to eliminate the residual conductive stringers in the lower edges of the field region, as shown by “C” in FIG. 12. This is achieved by the isotropic etching effect of a wet chemical that makes the field region of the first polysilicon layer round at the upper projected parts.

While this invention has been particularly shown and described with reference to preferred embodiments thereof, it will be understood by those skilled in the art that various changes in form and details may be made herein without departing from the spirit and scope of the invention as defined by the appended claims.

What is claimed is:

1. A method for fabricating a semiconductor device including a floating gate, a control gate deposited over said floating gate, and a dielectric interlayer interposed between control gate and floating gate, comprising:
sequentially depositing a tunnel oxide layer, a first polysilicon layer for said floating gate, and a nitride layer over a semiconductor substrate;
sequentially etching said nitride layer, first polysilicon layer, and semiconductor substrate to form a trench;
depositing an oxide layer over said substrate to fill said trench;
removing said oxide layer to said nitride layer to attain a trench isolation field region;
removing said nitride layer;
subjecting said field region to a wet-chemical treatment; and
depositing a second polysilicon layer for said floating gate over said substrate.

2. A method as defined in claim 1, wherein the step of subjecting said field region to said wet chemical treatment is performed so as to etch the oxide layer by 100 to 200 Å.

3. A method as defined in claim 1, the step of subjecting said field region to a wet chemical treatment is performed before the step of removing said nitride layer.
